(19) United States
(12) Patent Application Publication
(10) Pub. No.: US 2014/0042558 A1
(43) Pub. Date: Feb. 13, 2014

(54) METHOD OF FABRICATION OF SEMICONDUCTOR DEVICE

(71) Applicants: Martin Trevor Emeny, Malvern (GB); Peregrine Orr Jackson, Hereford (GB); David John Wallis, Malvern (GB)

(72) Inventors: Martin Trevor Emeny, Malvern (GB); Peregrine Orr Jackson, Hereford (GB); David John Wallis, Malvern (GB)

(73) Assignee: QINETIQ LIMITED, Farnborough, Hampshire (GB)

(21) Appl. No.: 13/810,303

(22) PCT Filed: Jul. 11, 2011
(86) PCT No.: PCT/GB2011/001033

§ 371 Date: Jul. 1, 2013

(30) Foreign Application Priority Data
Jul. 21, 2010 (GB) 1012236.4

(51) Int. Cl. H01L 29/78; H01L 29/66; H01L 21/02

(52) U.S. Cl. CPC H01L 29/78; H01L 21/02518; H01L 29/66477
USPC 257/410; 438/478; 257/288; 257/629; 438/197

(57) ABSTRACT

The invention relates to a method of fabricating a semiconductor device, the method including: providing a stacked semiconductor structure having a substrate, a buffer layer and one or more device layers; depositing a layer of AlSb on one or more regions of the upper surface of the stacked structure; and oxidising the AlSb layer in the presence of water to form a layer of aluminium oxide on the one or more regions of the upper surface. The semiconductor device is preferably a field effect transistor, and the method preferably includes the additional step of depositing source, drain and/or gate electrodes. In preferred embodiments, the method is controlled so as to avoid exposing the intermediate AlSb structure to the atmosphere and/or the oxidation step is conducted at a temperature between 100° and 300° C.

The invention relates generally to a method of fabricating a semiconductor device, particularly a semiconductor device comprising surface dielectric materials. More particularly, the invention relation to the fabrication of field effect transistors and precursors thereof, and related devices and uses. The invention is also concerned with a method of forming a passivation layer on a semiconductor device.

Semiconductor devices such as field effect transistors (FETs) are typically fabricated by first growing a stacked epitaxial structure on a substrate, and then subjecting the epitaxial stack to further processing steps. Examples of further processing steps include—but are not limited to—device etching and deposition of dielectric materials, electrodes and so on. During the growth stage, the oxygen content of the epitaxial layers can be very closely controlled by the use of ultra high vacuum (UHV) techniques such as molecular beam epitaxy. However, once removed from the growth chamber, the surface of the epitaxial stack readily oxidises in air to form a native oxide. In the case of AlInSb surfaces, which are of significant interest for indium antimonide (InSb) based fast transistors, XPS (X-ray photoelectron spectroscopy) measurements show that the native oxide produced by air exposure consists predominantly of indium oxides and antimony oxides, with low levels of aluminium oxide. Similarly, an InSb surface produces a native oxide consisting predominantly of indium oxides and antimony oxides.

In order to deposit a dielectric material on the stack, the native oxide is usually first removed from the semiconductor surface by a suitable technique. The dielectric layer (preferably a high-k dielectric such as Al₂O₃ or HfO₃) can then be deposited by a process such as atomic layer deposition. However, problems arise because the semiconductor/oxide interface can be hard to control, resulting in undesirable ‘charge trapping’ properties due to defects at the interface. A measure of the amount of charge which is trapped at the interface is given by the Defect Interface Trap (DIT) density and must be controlled in order to allow good control of the conducting channel by the gate in high frequency electronic devices.

The invention provides an improved semiconductor fabrication method, which method allows controlled oxidation of semiconductor surfaces and can enable the use of aluminium oxide as a high-k dielectric material, or as part of a high-k dielectric stack.

According to a first aspect of the invention, there is provided a method of fabricating a semiconductor device, the method comprising the steps of:
providing a stacked semiconductor structure comprising a substrate, a buffer layer and one or more device layers;
depositing a layer of AlSb on one or more regions of the upper surface of the stacked structure; and
oxidising the AlSb layer in the presence of water to form a layer of aluminium oxide on the one or more regions of the upper surface.

Preferably, the aluminium oxide layer comprises the pure oxide (Al₂O₃), but the oxide layer may also comprise AlO_{z}, AlO_{z}:OH and/or other hydrated aluminium oxides. The aluminium oxide layer may include a small amount of AlSb_{y}O_{z}, but is preferably substantially free from antimony.

In the invention, the upper surface of a stacked epitaxial structure (also referred to as a semiconductor stack, or a stacked semiconductor structure) is provided with an aluminium oxide layer by first depositing a layer of AlSb (aluminium antimonide) on one or more regions of said surface, and then oxidising the AlSb layer in the presence of water to form a layer of aluminium oxide on the one or more regions. In this way, an aluminium oxide layer is produced in a controlled manner from the deposited AlSb layer. Depending on its thickness, the aluminium oxide layer may be wholly or partly resistant to further oxidation in air. Formation of the aluminium oxide layer can provide several important benefits, including: enabling the epitaxial structure to be removed from the growth chamber for further ex-situ processing, provision of a diffusion barrier to prevent inter-diffusion of the surface of the epitaxial stack with layers subsequently deposited thereon (such as, for example, metal layers) and/or use of the aluminium oxide as a high-k dielectric material layer, particularly use as a gate dielectric, or as part of a gate dielectric stack, preferably in a MOS field effect transistor device.

It is known that an oxide comprising aluminium oxide can be formed from an aluminium-bearing Group III-V semiconductor material by exposing the aluminium-bearing Group III-V semiconductor to a water-containing environment at a temperature of at least 375° C. (See WO 92/12536 to Holonyak and Dallesasse.) The method of WO 92/12536 has particular application to Al-bearing Group III-V arsenides and phosphides, including ternary and quaternary materials, and is typically used to produce oxide layers having a thickness in the range 1 to 25 μm.

The inventors have found that a good quality aluminium oxide layer can be produced on a semiconductor surface by first depositing a layer of aluminium antimonide (AlSb) on one or more regions of said surface (thereby forming an intermediate structure having an AlSb layer) and then oxidising the AlSb layer in the presence of water. The use of AlSb for the production of an aluminium oxide layer has several important technical advantages over other aluminium-bearing Group III-V semiconductor materials: firstly, AlSb is a binary semiconductor which is convenient to deposit by an epitaxial technique; secondly, antimony (Sb) is driven off in the oxidation process, leaving little or no residual Sb in the oxidised layer; and thirdly, AlSb contains no disadvantageous semiconductor inclusions such as In or Ga (InO and GaO are poor gate dielectrics, so residual oxides of In and/or Ga are undesirable in the aluminium oxide layer formed by the invention). Moreover—although the method of the invention can be used with stacked semiconductor structures comprising a range of semiconductor materials (such as, for example, GaAs or InGaAs devices, and their precursor structures)—for antimonide-based devices such as InSb or GaSb transistors, it is particularly convenient to use an antimonide layer.

The AlSb layer is preferably deposited by an epitaxial growth technique. Such techniques are well known to the skilled person and include metal-organic chemical vapour deposition (MOCVD), molecular beam epitaxy (MBE), atomic layer deposition (ALD), migration enhanced molecular beam epitaxy (MEMBE), physical vapour deposition (PVD) and chemical beam epitaxy (CBE). MBE is a particularly preferred technique because it is a UHV deposition method which excludes contaminants and provides controlled growth conditions. However, in some circumstances MOCVD may be preferred over MBE.

By exposing an AlSb layer deposited on an epitaxial semiconductor stack to water for various durations, the inventors have found that the process is self limiting and that only the AlSb layer is oxidised. Moreover, substantially all of the AlSb layer can be converted to aluminium oxide, which means that the thickness of the deposited AlSb layer can be used to control the thickness of the aluminium oxide layer. Because AlSb and aluminium oxide have different lattice parameters, the thickness of the aluminium oxide layer is related to, but not necessarily the same as, the thickness of the AlSb layer.

The use of an epitaxial technique for AlSb deposition allows the thickness of the AlSb layer to be controlled accurately at the monolayer level. The critical thickness for relaxation of a crystalline AlSb layer is approximately 5 monolayers on (for example) a 35% AlInSb buffer layer. However, AlSb thicknesses greater than this can be deposited in the method of the invention because the AlSb is converted into amorphous aluminium oxide, and the presence of dislocations in the AlSb will not degrade its material quality.

In one preferred embodiment of the invention, the aluminium oxide layer acts as a passivation layer (that is, a layer which prevents further surface oxidation when the stacked semiconductor structure is exposed to the atmosphere). The inventors have found that, in order to provide surface passivation, the aluminium oxide layer preferably has a thickness of 2.5 nm or more, more preferably has a thickness in the range 2.5 nm to 10 nm and even more preferably has a thickness in the range 3.5 nm to 10 nm. In order to produce an aluminium oxide layer suitable for use as a passivation layer, AlSb is conveniently deposited to a thickness of at least 8 to 12 monolayers. Ideally, the thickness of the AlSb is no more than 35 monolayers.

A stacked semiconductor structure having an aluminium oxide passivation layer produced by the invention can be removed from the oxidation chamber and subjected to further device processing steps. Preferably, the AlSb is deposited on the entire upper surface of the stacked semiconductor structure.

The inventors have found that an aluminium oxide layer having a thickness of less than about 2.5 nm (which is equivalent to a deposited AlSb layer about 8 monolayers thick) is not fully stable to the atmosphere and, as a result, is generally unsuitable as a passivation layer. However, the method of the invention nevertheless produces an aluminium oxide layer having good material properties—specifically a low defect density—and this means that it can be used either as a dielectric material layer, or as an interface layer for the subsequent deposition of one or more further material layers. The use of an aluminium oxide layer as a controlled interface for the subsequent deposition of high-k dielectric materials can ameliorate, or substantially avoid, the ‘charge trapping’ problems associated with prior art methods of forming dielectric layers in semiconductor devices.

In other words, the DIT density can be controlled, thereby improving high frequency performance.

In another preferred embodiment of the invention, therefore, the AlSb layer is deposited to a thickness which produces, upon oxidation, an aluminium oxide layer capable of acting as a dielectric material layer and/or as a controlled interface for subsequent deposition of one or more further material layers. The thickness of the AlSb layer is preferably less than 8 monolayers if it is to be used as part of a dielectric stack (thereby producing an aluminium oxide layer of less than about 2.5 nm), but thicker layers (possibly up to about 35 monolayers—equivalent to about 10 nm of aluminium oxide) may be suitable if the aluminium oxide is to form the entirety of the gate dielectric on its own.

The one or more further material layers may be one or more metal layers, which metal layers may be used, for example, as the source, drain and/or gate electrodes of FET devices. In that case, the aluminium oxide layer can act as an effective diffusion barrier for preventing the interaction of the semiconductor surface with the metal layer or layers, or as a gate dielectric material. The electrodes may be formed in any suitable way, for example by depositing one or more metal layers in the desired electrode region, or by depositing and subsequently etching a metal layer to form the electrode structure or structures.

Alternatively, the one or more further material layers can be one or more oxide layers, preferably one or more layers of a high-k dielectric material. In that case, the aluminium oxide layer forms an interface layer for a dielectric material or dielectric stack, or forms part of a dielectric stack. Optionally, a metal layer (more specifically, a gate electrode) is deposited onto the dielectric stack.

In either case, further processing steps (that is, steps conducted after oxidation of the one or more AlSb layers) are preferably conducted under controlled conditions, so as to prevent uncontrolled oxidation of the aluminium oxide layer.

The one or more layers of AlSb are deposited on one or more regions of the upper surface of the stacked semiconductor structure. It will be understood by the skilled person that an epitaxial stack for a semiconductor device typically comprises a buffer layer grown upon a substrate, and one or more device layers grown upon the buffer layer. By upper surface is meant the semiconductor surface furthermost from the substrate, in other words the outermost surface of the one or more device layers. This can also be regarded as the top surface of the stack, and is typically—but not necessarily—the uppermost surface in the direction of epitaxial growth.

The stacked structure may comprise any suitable substrate, many examples being known to the skilled person. Preferably, the substrate comprises GaAs or Si.

The buffer layer is used to separate the active part of the device from any defects generated at the substrate to buffer interface and/or to generate any desirable properties such as strain in the active part of the device. Again, the buffer layer may comprise any suitable material or combination of materials, of which the skilled person is well aware. The method of the invention is particularly (although not exclusively) applicable to the fabrication of Group III-V devices, particularly indium antimonide devices, and more particularly InSb-based transistors and precursor structures thereof. Hence, the buffer layer preferably comprises a Group III-V semiconductor, more preferably a ternary Group III-V semiconductor and even more preferably, especially in the specific case of an FET, AlₓIn₁₋ₓSb.

The one or more device layers are chosen to provide a stacked semiconductor structure suitable for use as a particular device, or as a precursor structure for a particular device. Suitable materials for the device layers include—but are not limited to—Group III-V materials (particularly antimonides such as InSb, GaSb, AlInSb, InAsSb and GaInAsSb) and Group IV materials. Preferably, the semiconductor device is a transistor, or a precursor structure for a transistor, and more preferably the semiconductor device is a field effect transistor, or a precursor structure for a field effect transistor. Accordingly, the stacked semiconductor structure preferably comprises one or more device layers including a channel layer. The channel layer may have any suitable structure (such as, for example, a quantum well—or Q-well—structure) and may be formed from any suitable semiconductor material or materials. Preferably, the channel layer comprises a Group III-V semiconductor or a Group IV semiconductor, and more preferably the channel layer comprises InSb or Sn.

The invention can be used in the fabrication of any transistor configuration, examples being a lateral field effect transistor (including a lateral Q-well FET) or a verticalfield effect transistor (also known as a tunnel FET).

Other possible device layers are upper and/or lower confinement layers, and/or doping layers.

The stacked semiconductor structure may be an ‘as grown’ structure (that is, an epitaxial stack which has not yet been subjected to further processing steps), or may already have been subjected to one or more processing steps (such as, for example, a patterning technique). Hence, the stacked structure may have a planar or substantially planar upper surface, or may have a structured upper surface comprising mesas and so on.

The stacked semiconductor structure may have been processed to remove native oxide(s). However, in a preferred embodiment, the AlSb deposition step is conducted as a final step in the epitaxial growth of the stacked semiconductor structure, thereby substantially avoiding the formation of native oxide(s). This provides a convenient and simple embodiment of the invention.

The AlSb is deposited on one or more regions of the upper surface of the stacked semiconductor structure, the one or more regions being chosen to provide one or more layers of aluminium oxide at desired positions on the stacked semiconductor structure. The one or more regions may include horizontal surface regions, vertical surface regions (including mesa sidewalls) and/or inclined surface regions. The skilled person will be aware of techniques for masking surface regions where the AlSb layer is not required, examples being use of a layer of resist or sacrificial metal or dielectric layers defined by e-beam or photo lithography.

In one preferred embodiment of the invention, a layer of AlSb is deposited on one region of the upper surface, preferably the whole of the upper surface. This is particularly applicable to an ‘as grown’ stacked semiconductor structure having a planar or near planar upper surface and/or where the aluminium oxide layer is being fabricated as a passivation layer.

In another preferred embodiment, the semiconductor device is a lateral FET device, the one or more device layers includes a channel layer, the stacked semiconductor structure has a planar (‘as grown’) upper surface and the AlSb is deposited on the entire upper surface of the stacked structure.

In yet another preferred embodiment, the semiconductor device is a tunnel FET device, the one or more device layers includes a channel layer, the stacked semiconductor structure has a structured upper surface and the one or more regions of the upper surface includes at least one mesa sidewall. In this way, an aluminium oxide layer can be formed on either or both sides of the vertical channel, preferably in the gate region.

In the case of an FET device, or an FET precursor structure, the AlSb layer is preferably deposited on a region(s) of the device which is located over the channel layer, so that the aluminium oxide layer can lie between a subsequently deposited gate electrode and the channel which needs to be controlled by the gate.

Depending on the semiconductor device configuration, the upper surface of the stack may be a channel layer, an upper confinement layer or another device layer. In the case of a field effect transistor, the AlSb layer is typically deposited onto the channel layer (preferably an InSb or Sn channel layer) or an upper confinement layer (preferably an upper confinement layer formed from AlₓIn₁₋ₓSb).

The invention has particular application to field effect transistors and hence, the semiconductor device is preferably a precursor structure for a field effect transistor. The method may comprise the additional steps of depositing source, drain and/or gate electrodes onto the stacked structure, so as to form a field effect transistor device. Preferably, the aluminium oxide layer is formed in the region of the gate electrode so that it can act as a gate dielectric layer, or comprise part of a gate dielectric stack. In the latter case, one or more further dielectric materials can be deposited on the aluminium oxide layer prior to depositing the gate electrode.

One way of forming the aluminium oxide layer in the region of the gate electrode is to deposit the AlSb in at least said region and oxidise the AlSb layer to form aluminium oxide. Alternatively, the aluminium oxide layer can be formed on the entire upper surface of the stacked semiconductor structure and subsequently etched, so that the aluminium oxide remains only where required. In general, the aluminium oxide is formed on at least the gate region of the stacked semiconductor structure. This can be achieved by depositing a layer of AlSb on one or more regions which include at least the gate region.

The AlSb layer is oxidised in the presence of water, preferably at a temperature between 100° and 300° C., and more preferably at a temperature between 150° and 250°. In order to obtain a good quality aluminium oxide surface, it is highly desirable to avoid exposing the intermediate AlSb structure to the atmosphere. Accordingly, the method is preferably controlled so as to avoid exposing the AlSb layer to the atmosphere, or any other oxygen-containing environment. One preferred method of excluding oxygen is to conduct the oxidation step under UHV conditions. Thus, the oxidation step can be conducted in a UHV chamber, typically with a base pressure of about 1×10⁻⁹ mBar or better, and using a partial pressure of water around 1.4×10⁻⁶ mBar as measured on an ion gauge attached to the chamber.

The AlSb deposition step and the oxidation step are typically conducted as separate processes, conveniently in separate reaction chambers. Thus, the method of the invention may include the step of transferring the intermediate AlSb structure from a first reaction chamber (typically, an epitaxial growth chamber) to a second reaction chamber. Desirably, the transfer step is conducted under conditions which exclude oxygen.

Once the aluminium oxide layer has been formed, an annealing step may be conducted to further improve the quality of the oxide. This may include the step of annealing in a so-called “forming gas” (typically H₂/N₂).

According to a second aspect, the invention provides a method of fabricating a semiconductor device, the method comprising the steps of:

epitaxially growing a stacked semiconductor structure comprising a substrate, a buffer layer and one or more device layers;
epitaxially growing a layer of AlSb on the upper surface of the stacked structure as a final step in the growth process, so as to form an AlSb capped structure; and
oxidising the AlSb layer in the presence of water to form a layer of aluminium oxide.

In the second aspect, the AlSb covers substantially all of the upper surface of the stacked semiconductor structure. Thus, a stacked semiconductor structure having an aluminium oxide capping layer is formed. The capping layer can be removed subsequently for device processing and/or can be etched to form a device or precursor device.

According to a third aspect of the invention, there is provided an FET or a precursor structure for an FET made by the method of the first or second aspect. The FET may be a lateral FET or a tunnel FET device. Preferably, the aluminium oxide layer lies in the region of the gate electrode, so that said layer can act as a gate dielectric material and/or form part of a gate dielectric stack.

According to a fourth aspect of the invention, there is provided a semiconductor device comprising a stacked structure including a substrate, a buffer layer and one or more device layers, and a layer of aluminium oxide on the upper surface of the stacked structure, wherein the aluminium oxide layer acts as an interface layer for the deposition of one or more further material layers. Preferably, the one or more further material layers are one or more high-k dielectric material layers, and the aluminium oxide layer forms part of a dielectric stack. Alternatively—or additionally—the one or more further layers may include one or more metal layers, particularly a gate electrode for a FET device.

According to a fifth aspect of the invention, there is provided the use of an aluminium oxide layer fabricated by the method of the invention as an interface layer for the subsequent deposition of one of more further material layers.

According to a sixth aspect of the invention, there is provided a method of passivating a semiconductor surface, said method comprising the steps of depositing a layer of AlSb on the semiconductor surface to form an AlSb capped surface, and oxidising the AlSb layer in the presence of water to form a layer of aluminium oxide.

According to a seventh aspect of the invention, there is provided a method of producing an oxide layer on a semiconductor surface, the method comprising the steps of depositing a layer of AlSb on said surface and oxidising said layer in the presence of water. Preferably, the semiconductor surface comprises a Group III-V material, more preferably a Group III-V material selected from the group consisting of InSb, GaSb, AlInSb, InAsSb and GaInAsSb.

According to an eighth aspect of the invention, there is provided a field effect transistor device comprising a substrate, a buffer layer, a channel layer, a gate dielectric layer and a gate electrode positioned over the gate dielectric layer, characterised in that the gate dielectric layer comprises aluminium oxide. One or more additional dielectric material layers may be position between the aluminium oxide layer and the gate electrode to form a gate dielectric stack. The aluminium oxide layer can be deposited by the method of the first aspect.

Any feature in one aspect of the invention may be applied to any other aspects of the invention, in any appropriate combination. In particular, method aspects may be applied to device aspects, and vice versa.

The invention will now be described with reference to the accompanying drawings in which;

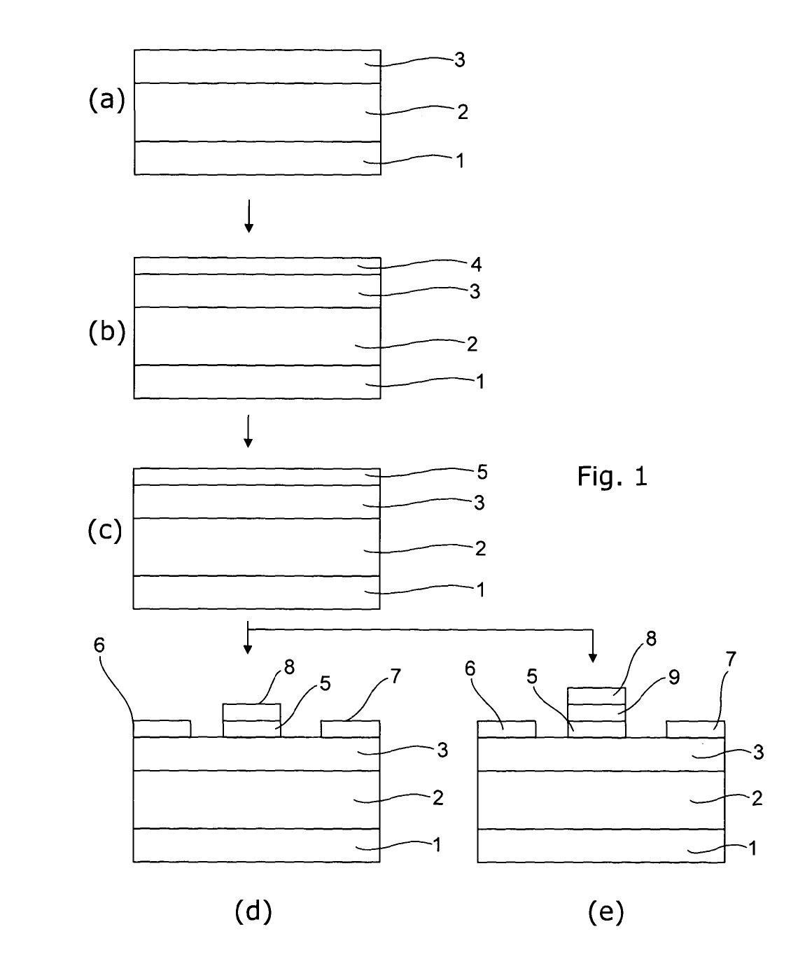

FIG. 1 illustrates the method of the invention for a lateral FET device;

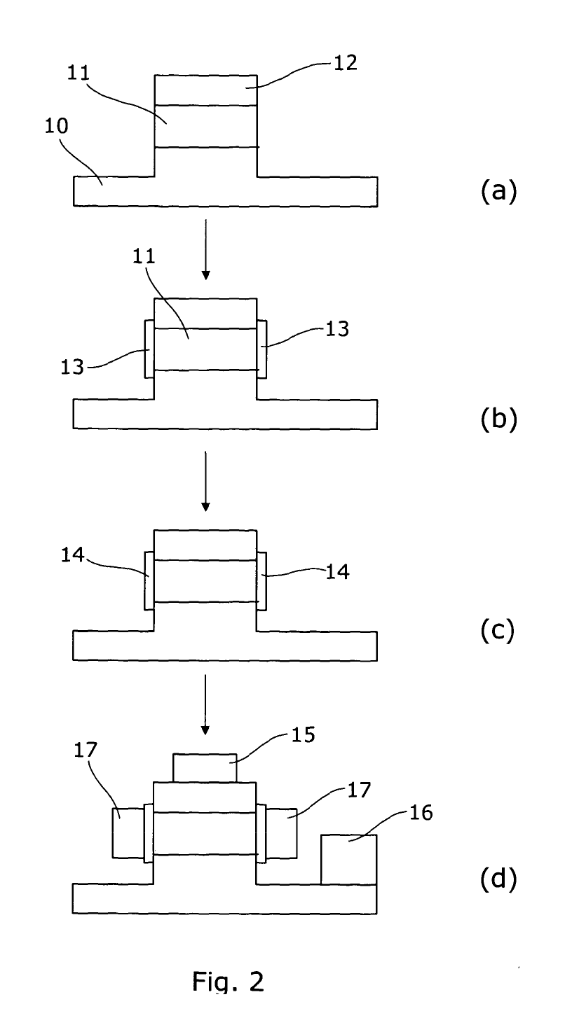

FIG. 2 illustrates the method of the invention for a vertical (tunnel) FET device;

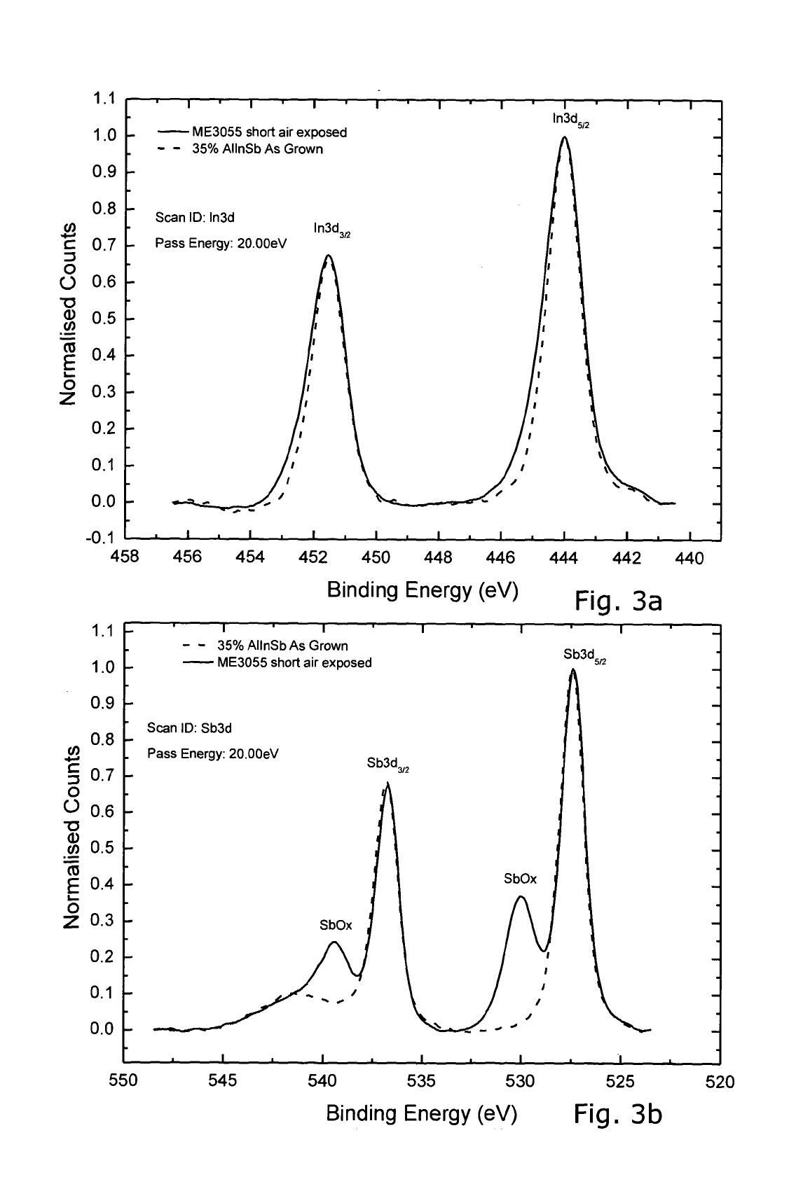

FIGS. 3a, 3b and 3c respectively show In (3d), Sb (3d) and Al (2p) XPS data from as-grown (with out air exposure) and air exposed (approximately 1 day) 40% AlInSb surfaces;

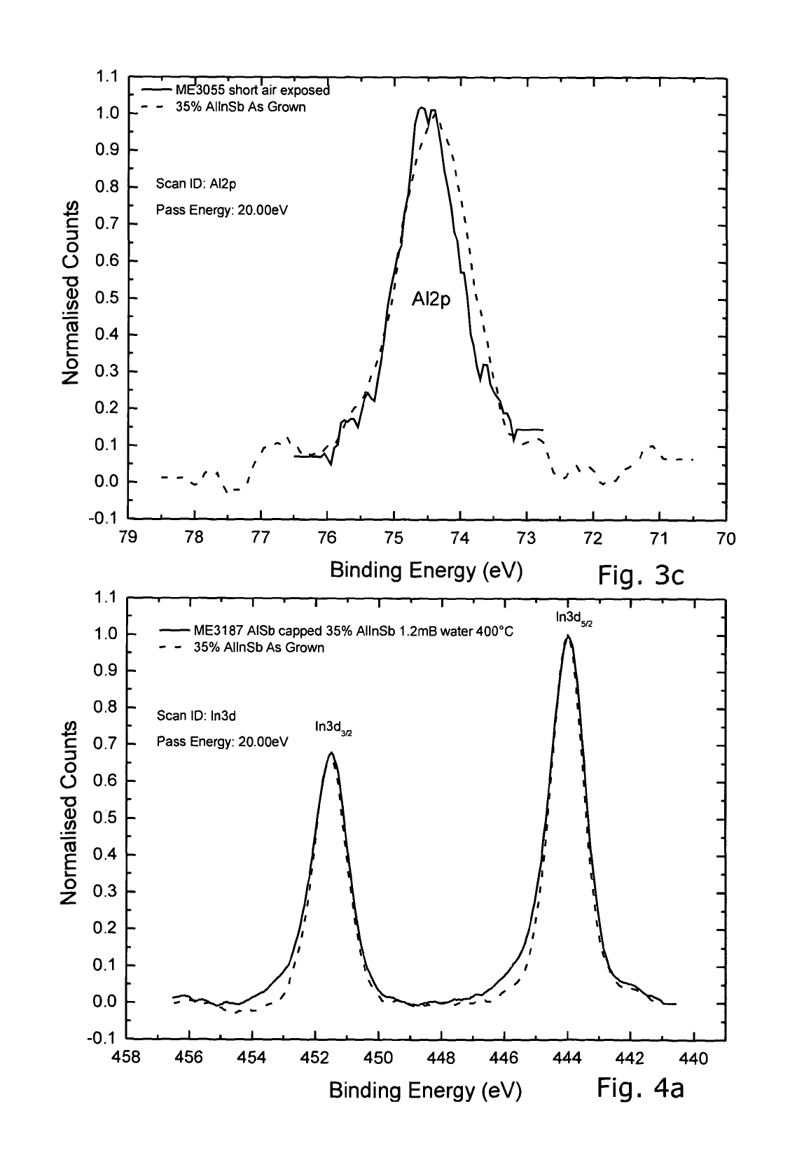

FIGS. 4a, 4b and 4c respectively show In (3d), Sb (3d) and Al (2p) XPS data comparing the surface composition of as-grown AlInSb and an AlInSb surface processed according to the invention;

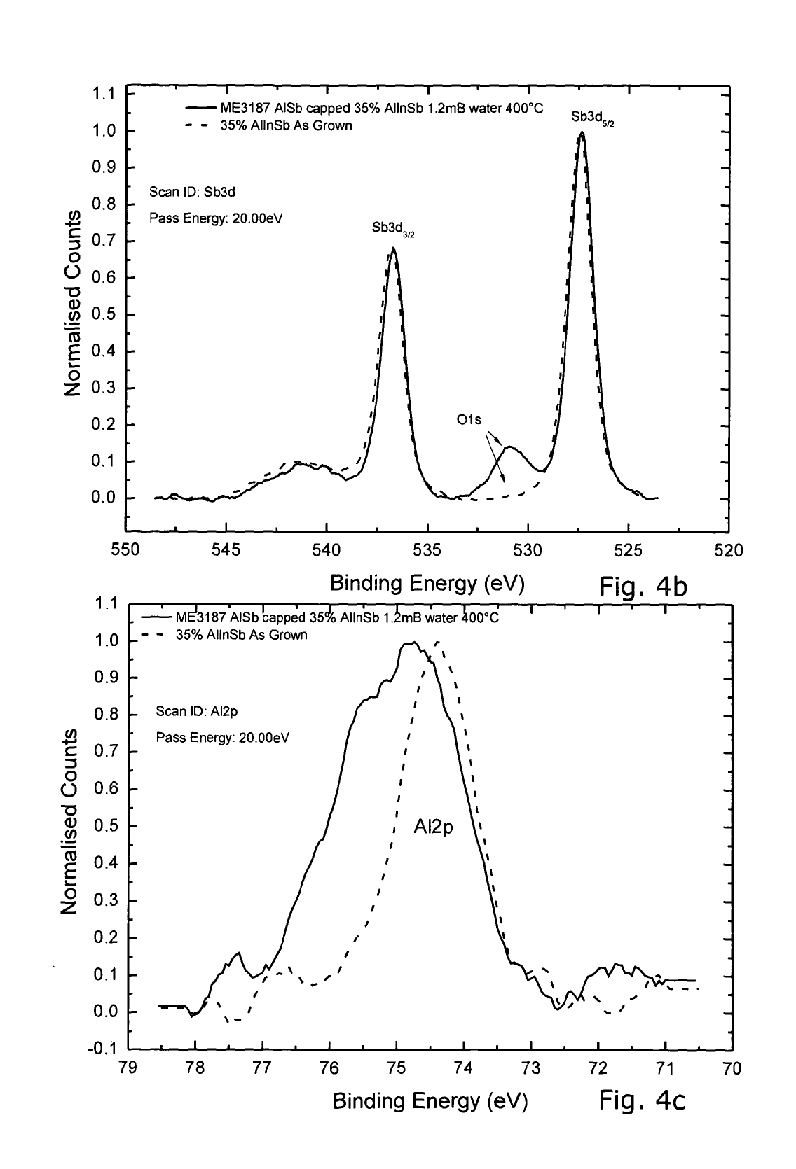

FIG. 5 shows the composition of the aluminium oxide layer produced by the method of the invention for various oxidation times from 1 hour to 5 hours;

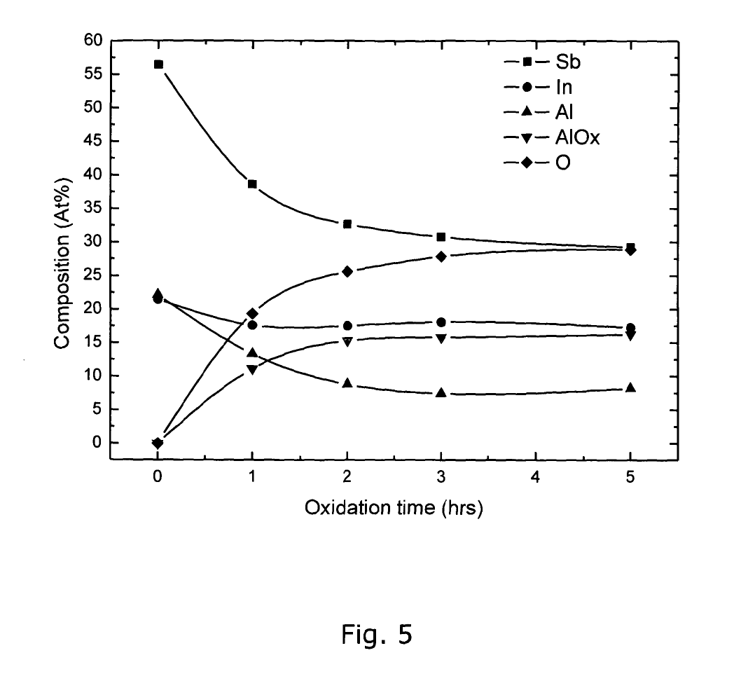

FIGS. 6a and 6b show, respectively, AFM images of the upper (AlInSb) surface of a stacked semiconductor structure before and after fabrication of an aluminium oxide layer according to the method of the invention;

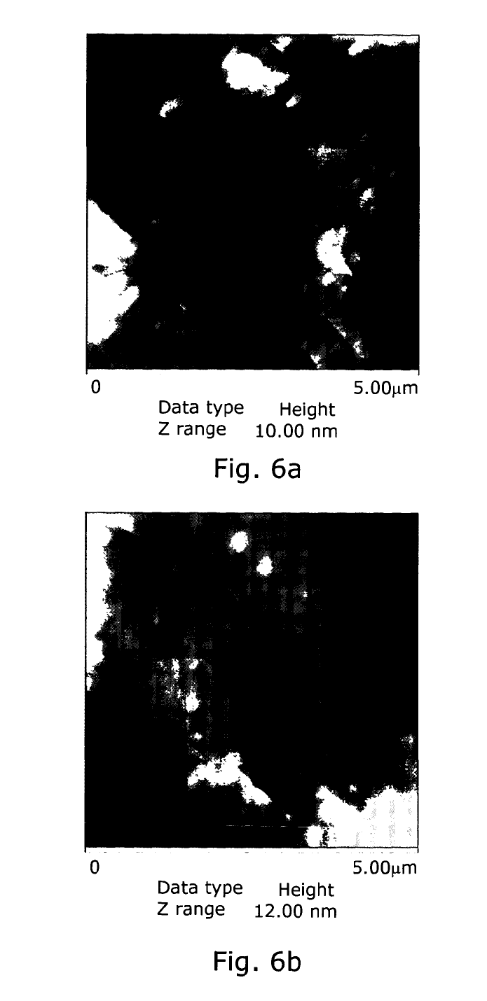

FIG. 7 shows the DC (direct current) transistor characteristics for a p-type field effect transistor incorporating an aluminium oxide gate dielectric layer fabricated by the method of the invention; and

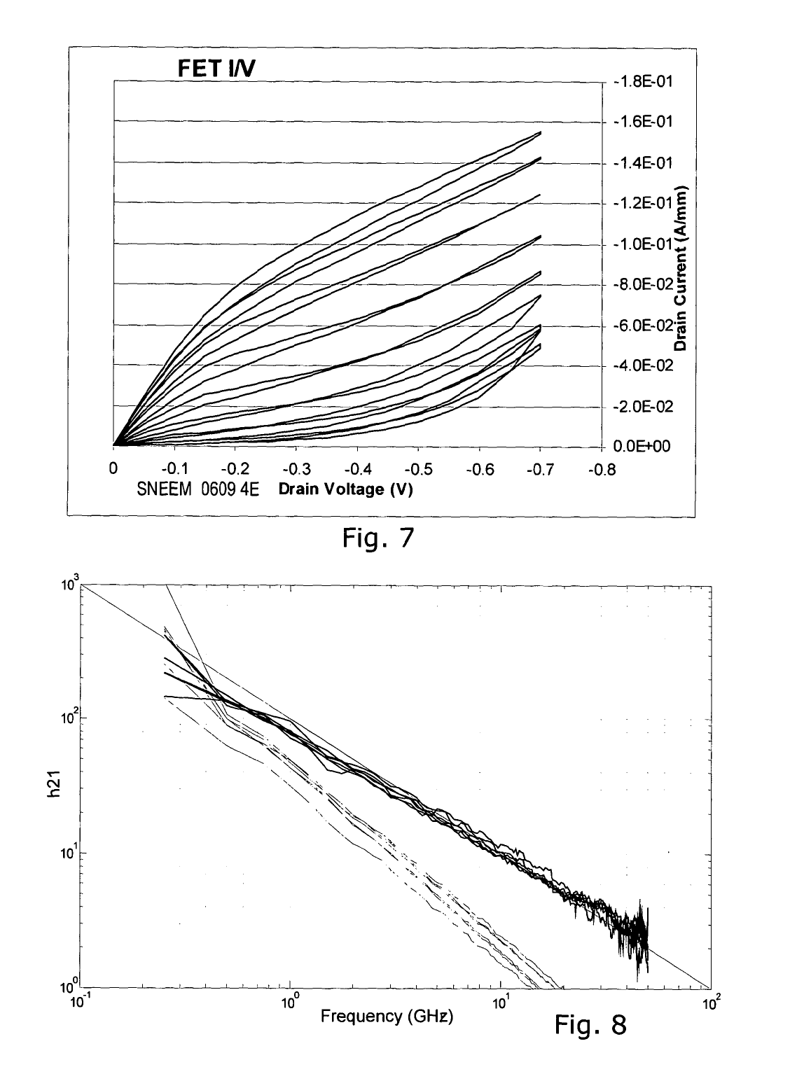

FIG. 8 shows h21 (or gain) against frequency for a group of p-type transistors incorporating an aluminium oxide layer produced by the method of the invention.

### ILLUSTRATION OF THE METHOD

The method of the invention is illustrated with reference to FIG. 1. First, a stacked semiconductor structure comprising a substrate 1, a buffer layer 2 and one or more device layers 3 is grown using any suitable epitaxial technique (e.g. MBE, MOCVD, PVD, ALD, MEMBE or CBE) (step (a)). Epitaxial growth techniques are well known to the skilled person and will not be described here. Preferably, the stacked structure is grown by MBE, which is a UHV technique in which the growth conditions can be carefully controlled.

In the case of an InSb based transistor, the stack might typically comprise a Si or GaAs substrate, an AlₓIn₁₋ₓSb buffer layer and an InSb Q-well channel layer. Alternatively, the channel can be formed from Sn. The stack might comprise other layers such as, for example, an AlₓIn₁₋ₓSb confinement layer above the Q-well layer.

An AlSb layer 4 is then deposited on the upper surface of the stacked semiconductor structure (step (b)) typically as a final step in the epitaxial growth process, thereby forming an AlSb capped structure. Preferably, the stacked structure and AlSb layer are grown in the same reaction chamber. The selected thickness of the AlSb layer depends on the desired end application; for a passivation layer, a thickness of at least 8 monolayers is generally required. For use as an interface layer, or as a dielectric material, the AlSb layer is typically deposited to a thickness of less than 8 monolayers, although thicker layers may also be used.

Next (step (c)) the AlSb capped semiconductor stack is transferred to a second reaction chamber and oxidised by exposure to a high purity water source. Oxidation results in the formation of an aluminium oxide layer 5. The stack is ideally transferred under controlled conditions—such as, for example, UHV—in order to prevent exposure of the AlSb layer to oxygen. The oxidation step is conducted by reacting the AlSb layer with water. This can be carried out in a UHV chamber with a base pressure of about 1×10⁻⁹ mBar or better. Typical process conditions for the oxidation step are a substrate temperature of 200° C. with a water partial pressure of about 1.4×10⁻⁶ mBar, measured on the ion gauge of the chamber. Higher partial pressures of water may be used for the oxidation process, although at higher pressures the pump down time to the base pressure of the chamber for any subsequent processing of additional layers is extended. Oxidation times are generally in the range 1 to 5 hours. No evidence for oxidation of the AlSb is seen at room temperature and elevated temperatures of 100° C. of more are typically required, preferably in the range 100° to 300° C. Ideally, oxidation takes place in the temperature range 150° to 250° C.

If the aluminium oxide layer has a thickness of around 3 nm or more, it can act as a passivation layer. The aluminium oxide capped semiconductor stack can then be removed from the oxidation chamber and subjected to any desired further processing steps.

Alternatively, the aluminium oxide layer may serve as a dielectric layer or as part of a dielectric stack. In optional step (d), a field effect transistor device is fabricated by first removing part of the aluminium oxide layer from the surface of the capped semiconductor stack (by an etching method or similar) and subsequently conducting a metallisation step to form source, drain and gate electrodes (6, 7 and 8). The aluminium oxide layer 5 is retained in the region of the gate electrode 8, so as to act as a gate dielectric material.

In alternative step (e), a field effect transistor device is fabricated by first depositing one or more layers of a high-k dielectric material 9 on the aluminium oxide layer 5, then removing the aluminium oxide and high-k dielectric layers from the surface of the stacked semiconductor structure (by an etching method or similar) and subsequently conducting a metallisation step to form source, drain and gate electrodes (6, 7 and 8). The aluminium oxide layer 5 and one or more high-k dielectric layers 9 are retained in the region of the gate electrode 8, thereby forming a gate dielectric stack, with the aluminium oxide layer acting as a controlled interface layer. In an alternative embodiment, the one or more layers of a high-k dielectric material can be deposited after the aluminium oxide layer 5 has been etched. Other permutations of the method will be apparent to the skilled person.

FIG. 2 illustrates the method of the invention for a tunnel FET device. First, a stacked semiconductor structure comprising a substrate and buffer layer 10, a channel layer 11 and an upper confinement layer 12 is grown using any suitable epitaxial technique, and then mesa etched to form a precursor device structure (step (a)).

In the case of an InSb based transistor, the stack might comprise a Si or GaAs substrate, an AlₓIn₁₋ₓSb buffer layer and an InSb channel layer. Alternatively, the channel can be formed from Sn. The upper confinement layer might comprise AlₓIn₁₋ₓSb.

An AlSb layer 13 is then deposited on the mesa sidewalls, on either side of channel layer 11 (step (b)). The AlSb layer may be deposited by MBE or other layer deposition techniques, such as CVD, MOCVD and so on. The thickness of the AlSb is suitable for growing an aluminium oxide layer suitable for use as a gate dielectric, or as part of a gate dielectric stack.

Next (step (c)) the AlSb capped semiconductor stack is transferred to a second reaction chamber and oxidised by exposure to a high purity water source. The stack is ideally transferred under controlled conditions—such as, for example, UHV—in order to prevent exposure of the AlSb surface to oxygen. The oxidation step is preferably conducted under conditions described above in relation to FIG. 1. Oxidation results in the formation of an aluminium oxide layer 14.

In step (d), a field effect transistor device is fabricated by conducting a metallisation step to form source, drain and gate electrodes (15, 16 and 17). If required, one or more layers of a high-k dielectric material can be deposited on the aluminium oxide layer prior to the metallisation step.

Comparison of as-Grown Surface, Air Oxidised Surface and Surface Produced by the Invention

FIGS. 3a, 3b and 3c respectively show In (3d), Sb (3d) and Al (2p) XPS data from as-grown (with out air exposure) and air exposed (approximately 1 day) 40% AlInSb surfaces. The shoulders seen on the In and Sb peaks indicate the presence of In—O and Sb—O bonds. The absence of a shoulder at high energy on the Al (2p) peak indicates that there is very little aluminium oxide present in both cases.

FIGS. 4a, 4b and 4c respectively show In (3d), Sb (3d) and Al (2p) XPS data comparing the surface composition of as-grown AlInSb and an AlInSb surface processed according to the invention. The XPS analysis shows that the oxide layer produced by the method of the invention comprises Al—O bonds only and that, in contrast to atmospheric oxidation, substantially no In—O or SbO bonds are formed. Thus, it can be concluded that the oxidation process is very different to the process which takes place in air, and also that the oxidation process displaces Sb from the AlSb film to produce pure (or nearly pure) aluminium oxide.

### Stability of the Aluminium Oxide Layer

An AlSb surface was epitaxially grown on an InSb-based semiconductor stack having an AlInSb upper surface, and exposed to water under UHV conditions (water partial pressure of 1.6×10⁻⁶ mBar) at 200° C., for various times between 1 and 5 hrs. The composition of the aluminium oxide layer produced from the AlSb was analysed for each oxidation time (see FIG. 5). It can be seen that the process was self limiting, and that only the AlSb layer was oxidised. Hence, it is concluded that the thickness of the aluminium oxide layer can be accurately controlled using the thickness of the deposited AlSb layer.

A thin AlSb layer (around 4 monolayers) was oxidised by the method of the invention to produce a layer of aluminium oxide about 1.5 nm thick, and subsequently exposed to air. XPS analysis concluded that further oxidation of the surface had occurred, resulting in the formation of In—O and Sb—O bonds. Hence, at a thickness of around 4 monolayers, the aluminium oxide layer produced by the invention is not fully stable to air and is unsuitable as a passivation layer. However, the thin layer is an effective diffusion barrier to prevent interaction of the surface of a stacked semiconductor structure with metal layers deposited thereon, provided that exposure to air is substantially prevented prior to and during the metallisation process. Such metal layers may be used as the gate metal for FET devices. Thin aluminium oxide layers may also be used as a gate dielectric, or as part of a gate dielectric stack.

A thicker AlSb layer (around 8 to 12 monolayers) was oxidised by the method of the invention to produce an aluminium oxide layer about 3 nm thick, and subsequently exposed to air. XPS analysis showed that no further oxidation occurred, even after 1 week. This indicates that an aluminium oxide layer produced from an AlSb layer of at least 8 to 12 monolayers is a good barrier to further oxidation and is stable (in other words, the aluminium oxide layer can act as a passivation layer). A stable oxide which is unchanged by air exposure allows a semiconductor surface to be removed from controlled atmospheric conditions (e.g. UHV) and subjected to further processing in a controlled manner. This is important for the reproducibility of device processing.

### Analysis of Aluminium Oxide Surface

FIG. 6a is an AFM (atomic force microscopy) image of the surface of a semiconductor stack typical of an InSb FET (in this particular case, the upper surface is AlInSb). FIG. 6b is an AFM image of an aluminium oxide surface produced on the semiconductor stack by the method of the invention, using a 12 monolayer layer of AlSb deposited on the AlInSb. It can be seen that the surface roughness of the aluminium oxide layer is similar to the AlInSb semiconductor surface prior to oxide formation. The surface is continuous, without significant defects such as pinholes, and conformal on the semiconductor surface.

### Effect of Aluminium Oxide Layer on Carrier Mobility

An important factor for the use of an oxide layer in an FET device is that it does not degrade the mobility of the carriers in the device. Table 1 compares the sheet resistivity of three InSb based Q-well structures typical of those used in p-type FET devices:

Structure 1 has no intentional oxide, Structure 2 is an identical semiconductor structure with a 12 monolayer layer of AlSb oxidised by exposure to air (that is, not according to the invention), and Structure 3 is an identical semiconductor structure with a 12 monolayer layer of AlSb oxidised by the method of the invention. It can be seen that the layer formed according to the invention shows no evidence of reduced mobility (as evidenced by sheet resistivity), whereas the material which was allowed to oxidise in air became immeasurable, i.e. high resistance.

TABLE 1
Sheet resistivities of p-type InSb Q-
well layers with different oxide caps

| | | Sheet Resistivity (ohms/square) | |
|---|---|---|---|
| Sample ID | Oxide cap | Room Temp | 77 K |
| Structure 1 | No oxide | 9480 | 9470 |
| Structure 2 | 12 monolayers | immeasurable | immeasurable |
| | AlSb oxidised | | |
| | in air | | |
| Structure 3 | 12 monolayers | 9280 | 8700 |
| | AlSb oxidised | | |
| | according to | | |
| | invention | | |

### Device Characteristics

FIG. 7 shows the DC (direct current) transistor characteristics for a p-type field effect transistor incorporating an aluminium oxide gate dielectric layer fabricated by the method of the invention. Each trace of current (I) against voltage (V) is for a different voltage applied to the gate. FIG. 7 shows that the gate is able to control the channel of a transistor and hence, that the deposited aluminium oxide layer is capable of acting as a high-k dielectric material.

FIG. 8 shows h21 (or gain) against frequency for a group of p-type transistors incorporating an aluminium oxide layer produced by the method of the invention. The plot shows two sets of data; the lower set of curves is the raw data for several transistors and the higher set of curves is the same data, for the same transistors, with the losses due to the measurement system removed. The upper set of curves has been extrapolated by standard methods to determine the speed of the devices and shows that the devices can operate up to 100 GHz.

It will be understood that the present invention has been described above purely by way of example, and modification of detail can be made within the scope of the invention. Each feature disclosed in the description, and (where appropriate) the claims and drawings, may be provided independently or in any appropriate combination.

Moreover, the invention has been described with specific reference to field effect transistors, and especially InSb FETs. However, because the use of dielectrics is a ubiquitous technology for the scaling of semiconductor devices, particularly FET devices, there is significant interest in looking at the production of oxides on other semiconductors. Thus, the method of the invention is widely applicable and may be used, for example, to deposit a controlled aluminium oxide layer onto material systems including InSb, GaSb, InAsSb, GaInAsSb, GaAs or InGaAs.

1. A method of fabricating a semiconductor device, the method comprising the steps of:
providing a stacked semiconductor structure comprising a substrate, a buffer layer and one or more device layers;
depositing a layer of AlSb on one or more regions of the upper surface of the stacked structure; and
oxidising the AlSb layer in the presence of water to form a layer of aluminium oxide on the one or more regions of the upper surface.

2. A method according to claim 1, wherein the AlSb layer is deposited by an epitaxial technique.

3. A method according to claim 2, wherein the epitaxial technique is MBE.

4. A method according to claim 1, wherein the method includes a masking step to form the one or more regions.

5. A method according to claim 1, wherein substantially all of the AlSb is converted to aluminium oxide.

6. A method according to claim 1, wherein the thickness of the aluminium oxide layer is related to the thickness of the deposited AlSb layer.

7. A method according to claim 1, wherein the AlSb layer is deposited to a thickness which, upon oxidation, produces an aluminium oxide layer capable of acting as a passivation layer.

8. A method according to claim 7, wherein the AlSb layer is deposited to a thickness of at least 8 monolayers.

9. A method according to claim 1, wherein the AlSb layer is deposited to a thickness which produces, upon oxidation, an aluminium oxide layer capable of acting as a dielectric material layer and/or as a controlled interface for subsequent deposition of one or more further material layers.

10. A method according to claim 9, wherein the AlSb layer is deposited to a thickness of less than 8 monolayers.

11. A method according to claim 9, wherein the one or more further material layers are layers of a high-k dielectric material.

12. A method according to claim 1, wherein the oxidation step is conducted at a temperature between 100° and 300° C.

13. A method according to claim 1, wherein the method is controlled so as to avoid exposing the intermediate AlSb structure to the atmosphere.

14. A method according to claim 13, wherein the oxidation step is conducted under UHV conditions.

15. A method according to claim 1, wherein the AlSb deposition step and oxidation step are conducted in separate reaction chambers.

16. A method according to claim 15, wherein the intermediate AlSb structure is transferred to a second reaction chamber under conditions which exclude oxygen.

17. A method according to claim 1, wherein the buffer layer comprises a Group III-V semiconductor.

18. A method according to claim 17, wherein the buffer layer comprises AlₓIn₁₋ₓSb.

19. A method according to claim 1, wherein the one or more device layers includes a channel layer.

20. A method according to claim 19, wherein the channel layer comprises a Group III-V semiconductor or a Group IV semiconductor.

21. A method according to claim 20, wherein the channel layer comprises InSb or Sn.

22. A method according to claim 1, wherein the substrate comprises GaAs or Si.

23. A method according to claim 1, wherein the semiconductor device is a precursor structure for a field effect transistor.

24. A method according to claim 1, wherein the semiconductor device is a field effect transistor and the method comprises the additional step of depositing source, drain and/or gate electrodes.

25. A method according to claim 1, wherein the semiconductor device is a FET and AlSb is deposited on one or more regions including at least the gate region.

26. A method according to claim 24, wherein one or more further dielectric materials are deposited on the aluminium oxide layer prior to depositing the gate electrode.

27. A method of fabricating a semiconductor device, the method comprising the steps of:
epitaxially growing a stacked semiconductor structure comprising a substrate, a buffer layer and one or more device layers;
epitaxially growing a layer of AlSb on the upper surface of the stacked structure as a final step in the growth process, so as to form an AlSb capped structure; and
oxidising the AlSb layer in the presence of water to form a layer of aluminium oxide.

28. A field effect transistor made by the method of claim 23.

29. A semiconductor device comprising a stacked structure including a substrate, a buffer layer and one or more device layers, and a layer of aluminium oxide on the upper surface of the stacked structure, wherein the aluminium oxide layer acts as an interface layer for the deposition of one or more further material layers.

30. (canceled)

31. A method of passivating a semiconductor surface, said method comprising the steps of depositing a layer of AlSb on the semiconductor surface to form an AlSb capped surface, and oxidising the AlSb layer in the presence of water to form a layer of aluminium oxide.

32. A method of producing an oxide layer on a semiconductor surface, the method comprising the steps of depositing a layer of AlSb on said surface and oxidising said layer in the presence of water.

33. A field effect transistor device comprising a substrate, a buffer layer, a channel layer, a gate dielectric layer and a gate electrode positioned over the gate dielectric layer, characterised in that the gate dielectric layer comprises aluminium oxide.

34-35. (canceled)
